(19) United States
(12) Patent Application Publication
(10) Pub. No.: US 2004/0115565 A1
(43) Pub. Date: Jun. 17, 2004

(54) Method for patterning a layer of a low dielectric constant material

(75) Inventors: Stephan E. Lassig, Danville, CA (US); Ian James Morey, San Jose, CA (US)

Correspondence Address: MARTINE & PENILLA, LLP, 710 LAKEWAY DRIVE, SUITE 170, SUNNYVALE, CA, 94085, US

(73) Assignee: LAM RESEARCH CORPORATION, FREMONT, CA

(21) Appl. No.: 10/644,269

(22) Filed: Aug. 19, 2003

Related U.S. Application Data
(63) Continuation-in-part of application No. 09/346,068, filed on Jul. 1, 1999, now abandoned.

(51) Int. Cl. G03C 5/58; H01L 21/302

(52) U.S. Cl. 430/313; 430/311; 430/322; 430/323; 430/324; 438/700

(57) ABSTRACT

In a method for patterning a layer of a low dielectric constant material a surface imaging material is applied on a layer of a low dielectric constant material. A pattern is then defined in the surface imaging material. Next, the patterned surface imaging material is hardened so that the patterned surface imaging material functions as a hard mask. If the patterned surface imaging material has silicon incorporated therein, then the material may be hardened by exposure to an oxygen containing plasma. Otherwise, the patterned surface imaging material may be hardened by incorporating silicon into the material, e.g., by silylation, and exposing the material to an oxygen containing plasma. Thereafter, the pattern defined in the surface imaging material is transferred to the layer of the low dielectric constant material.

### CROSS-REFERENCE TO RELATED APPLICATIONS

This application is a continuation-in-part of application Ser. No. 09/346,068, filed on Jul. 1, 1999. The disclosure of this application is incorporated herein by reference.

### BACKGROUND OF THE INVENTION

The present invention relates generally to the fabrication of integrated circuits and, more particularly, to a method for patterning a layer of a low dielectric constant material.

The trend in integrated circuit (IC) technology toward smaller feature sizes is approaching the use of features that are 0.18 μm and smaller. At such small feature sizes, dielectric materials having low dielectric constants, k, must be used in intermetal dielectric layers to obtain high device speeds and to reduce crosstalk between metal lines. At present, dielectric materials having low dielectric constants fall into three broad categories: doped oxides, organic materials, e.g., polymers, and nanoporous materials. The doped oxide materials may be etched for patterning using a fluorine chemistry and, in many cases, do not require a hardmask for etching. On the other hand, the organic materials require the use of a hardmask for etching because the chemistry used to etch these materials, e.g., an oxygen or hydrogen chemistry, is the same as or similar to the chemistry used to strip the photoresist material. In many cases, the application of the hardmask and the application of the photoresist must be performed in two separate modules. This is a disadvantage in a fab because it requires more process steps, which makes the fabrication process more complex and more expensive.

FIGS. 1A to 1E illustrate the conventional patterning process used for low dielectric constant (“low k”) polymeric materials. As shown in FIG. 1A, a layer 12 of the low k polymeric material is first formed on substrate 10 by an appropriate technique, e.g., spin coating. Next, as shown in FIG. 1B, a hardmask 14 is formed on layer 12 of low k polymeric material. Hardmask 14 is typically silicon dioxide or silicon nitride and may be formed by known techniques, e.g., plasma CVD. Once hardmask 14 is formed, layer 12 of low k polymeric material is patterned with standard single layer photoresist material. FIG. 1C shows photoresist 16 after it has been exposed and developed to define a pattern therein using well-known techniques. As shown in FIG. 1D, the pattern is then transferred to hardmask 14 using an appropriate etching technique, e.g., plasma etching with a fluorine chemistry. Next, as shown in FIG. 1E, the pattern is transferred to layer 12 of low k polymeric material using an appropriate etching technique, e.g., plasma etching in an oxygen-containing chemistry.

During the process of transferring the pattern to layer 12 of low k polymeric material, the photoresist 16 and layer 12 of low k polymeric material etch at similar rates because they are both polymeric materials. As such, hardmask 14 is needed to ensure the pattern fidelity into layer 12 of low k polymeric material in the event photoresist 16 erodes before the low k polymeric material is completely etched. When the hardmask 14 is used, especially when etching polymeric materials, the goal of the etching process is to consume as much of photoresist 16 as possible. However, residual photoresist often remains on hardmask 14 after the etch process (see photoresist 16 in FIG. 1E). This residual photoresist is undesirable because it may be difficult to remove once the low k polymeric material has been etched.

In the conventional patterning scheme illustrated in FIGS. 1A to 1E, the steps shown in FIGS. 1B and 1C may be implemented using other known bi-layer surface imaging sequences. A bi-layer resist scheme is typically used to enhance the resolution of the lithographic process. One such surface imaging technique is referred to as the chemical amplification of resist lines (CARL). In the CARL patterning process, a non-photosensitive polymer, which is typically a novolak-based resin, is first spun onto the substrate. This layer, which typically has the same thickness as standard photoresist, provides local and global planarization. A much thinner layer of a CARL surface imaging material, which is photosensitive, is then formed on the planarization layer.

The CARL surface imaging material enables the highest possible resolution to be obtained because a smaller depth of focus may be used. The CARL surface imaging material may be exposed and “developed” in a manner similar to that used for standard photoresist. Thereafter, the CARL surface imaging material is subjected to processing known as silylation. This processing chemically incorporates silicon into the top surface of the CARL surface imaging material to allow it to form a thin hardmask upon exposure to an oxidizing plasma etch. This hardmask is then used to transfer the pattern into the planarization layer by, e.g., plasma etching with an oxygen-containing chemistry. Once the pattern is transferred to the planarization layer, etching of the low k polymeric material may commence.

On the one hand, the CARL patterning process is desirable because it provides improved resolution, which is particularly important at smaller feature sizes. On the other hand, the incorporation of the CARL patterning process into the process flow for an IC is disadvantageous because it still requires the use of two layers, namely the planarization layer and the layer of CARL surface imaging material. Consequently, the incorporation of the CARL patterning process in a process flow for an IC makes the process flow more complex and more expensive. In view of the foregoing, there is a need for a method for patterning a layer of a low dielectric constant material that does not require the use of two layers and does not require the separate formation of a hardmask.

### SUMMARY OF THE INVENTION

Broadly speaking, the present invention provides a technique for patterning a layer of a low dielectric constant material in which a surface imaging material is applied directly on the low dielectric constant material. This technique avoids the need to use two layers, e.g., a hardmask and a photoresist layer, in the patterning process.

In one aspect of the invention, a method for patterning a layer of a low dielectric constant material is provided. In this method a surface imaging material, which is photodefinable and hardenable, is applied on a layer of a low dielectric constant material. A pattern is then defined in the surface imaging material. Next, the patterned surface imaging material is hardened so that the patterned surface imaging material functions as a hard mask. Thereafter, the pattern defined in the surface imaging material is transferred to the layer of the low dielectric constant material.

In one embodiment, the surface imaging material has a thickness in the range from about 500 angstroms to about 2,500 angstroms. In one embodiment, the low dielectric constant material is selected from the group including doped oxide, organic materials, and nanoporous materials. In one embodiment, the layer of the low dielectric constant material has a thickness in the range from about 3,000 to about 10,000 angstroms.

In one embodiment, the hardening of the patterned surface imaging material includes incorporating silicon into the patterned surface imaging material and exposing the patterned surface imaging material to an oxygen containing plasma. In another embodiment, the surface imaging material has silicon incorporated therein, and the hardening of the patterned surface imaging material includes exposing the patterned surface imaging material to an oxygen containing plasma.

In another aspect of the invention, a method for forming an integrated circuit is provided. This method, which incorporates the method for patterning a layer of a low dielectric constant material of the present invention, may be used in via first, trench first, and self-aligned dual damascene applications.

The method for patterning a layer of a low dielectric constant material of the present invention advantageously reduces the number of process steps required to pattern a low dielectric constant material. This makes the process flow for an IC less complex and less expensive. In addition, because the method does not use standard photoresist coated on a hardmask in the patterning process, there is no need to remove residual photoresist from the hardmask once the low dielectric constant material has been etched. The method also increases the etch rate of the low dielectric constant material. The reason for this increased etch rate is that the elimination of the standard photoresist reduces loading. Furthermore, because of such reduced loading, the method may enhance rate and profile control in the narrowest features.

It is to be understood that the foregoing general description and the following detailed description are exemplary and explanatory only and are not restrictive of the invention, as claimed.

### BRIEF DESCRIPTION OF THE DRAWINGS

The accompanying drawings, which are incorporated in and constitute part of this specification, illustrate exemplary embodiments of the invention and together with the description serve to explain the principles of the invention.

FIGS. 1A to 1E illustrate the conventional patterning process used for low dielectric constant polymeric materials.

FIGS. 2A to 2C illustrate the method for patterning a layer of a low dielectric constant material in accordance with one embodiment of the invention.

FIGS. 3A to 3E illustrate another embodiment of the method of the present invention in a via first dual damascene application.

FIGS. 4A to 4E illustrate yet another embodiment of the method of the present invention in a trench first dual damascene application.

FIGS. 5A to 5D illustrate still another embodiment of the method of the present invention in a self-aligned dual damascene application.

### DETAILED DESCRIPTION OF THE PREFERRED EMBODIMENTS

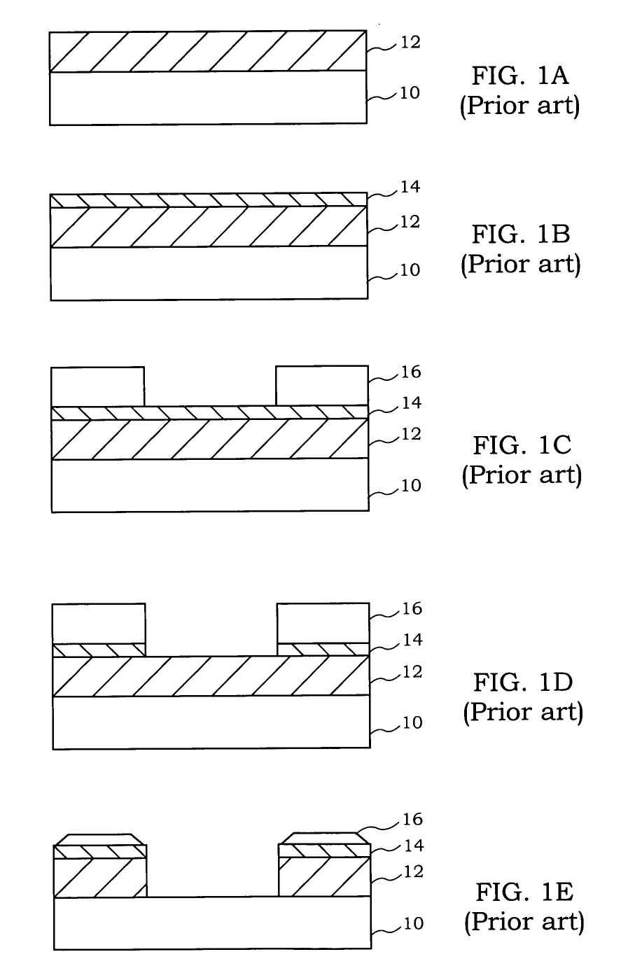

The present preferred embodiments of the invention will now be described in detail with reference to the accompanying drawings. FIGS. 1A to 1E are discussed above in the “Background of the Invention” section.

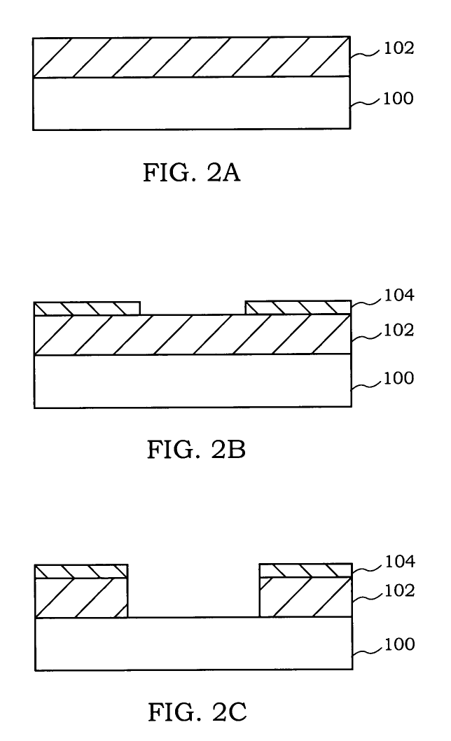

FIGS. 2A to 2C illustrate the method for patterning a layer of a low dielectric constant material in accordance with one embodiment of the invention. FIG. 2A shows substrate 100 with a layer 102 of a low dielectric constant material formed thereon. When layer 102 forms an intermetal dielectric layer, substrate 100 may be a layer of metal, e.g., aluminum or copper, coated with a diffusion barrier, e.g., silicon dioxide or silicon nitride. Those skilled in the art are familiar with techniques for forming metal layers, e.g., physical vapor deposition (PVD), and diffusion barriers, e.g., chemical vapor deposition (CVD). Layer 102 may be formed of any suitable low dielectric constant material. As used in connection with the description of the invention, the phrases “low dielectric constant material” and “low k material” refer to dielectric materials having a dielectric constant, k, of less than about 3.5. Suitable low k materials include, by way of example, doped oxides, organic materials, e.g., polymeric materials, and nanoporous materials.

In one embodiment of the invention, layer 102 is formed of a low k polymeric material. Suitable low k polymeric materials include, by way of example, fluorinated poly(arylene ethers), which are commercially available from AlliedSignal Inc. under the trade designation FLARE (k=2.7-2.8), benzocyclobutene (BCB) and SiLK I Semiconductor Dielectric resins, which are commercially available from The Dow Chemical Company (k for SiLK I films=2.65-2.75), and polytetrafluoroethylene (PTFE) nanoemulsion-based materials, which are commercially available from W.L. Gore & Associates, Inc. under the trade designation SPEEDFILM IC Dielectric (k=1.9-2.0). As is well known to those skilled in the art, layers of such low k polymeric materials may be formed by spin coating.

In another embodiment of the invention, layer 102 is formed of a nanoporous material. One suitable nanoporous material is nanoporous silica, which is commercially available from AlliedSignal Inc. under the trade designation NANOGLASS (k=2.0). This nanoporous material also may be formed by a spin-on technique.

After the layer of low k material is formed on the substrate, a layer of surface imaging material is formed on the low k material. FIG. 2B shows layer 104 of surface imaging material formed on layer 102 of low k material. As used in connection with the description of the invention, the phrase “surface imaging material,” which is used to form layer 104, refers to any suitable material that is photodefinable (so that it can be patterned) and hardenable (so that it can be converted into a hardmask). In one embodiment, the surface imaging material does not contain silicon and is hardenable by incorporating silicon therein, e.g., by a suitable silylation process, and subsequently exposing the material to an oxygen containing plasma. In another embodiment, the surface imaging material contains silicon and is hardenable by exposure to an oxygen containing plasma.

In one embodiment of the invention, layer 104 is formed of a CARL surface imaging material, i.e., a surface imaging material used in chemical amplification of resist lines (CARL) patterning processes. Suitable CARL surface imaging materials are commercially available from Clariant AG under the trade designations AZ CP-248CA PHOTORESIST (for 248 nm/193 nm, i.e., crossover or dual wavelength, applications) and AZ CP 365 PHOTORESIST (for 365 nm applications). In the CARL process, the basic polymer contains maleic anhydrides. Thus, those skilled in the art will recognize that other comparable photoresists, e.g., co- or terpolymers of maleic acid anhydride with trimethylallysilane, styrene, or maleimide for the resin, also may be used. More recently, t-BOC blocked maleimides or t-butylmethacrylate copolymers have been used.

It will be apparent to those skilled in the art that yet other surface imaging materials also may be used. By way of example, at 365 nm, for gas phase or top surface imaging, novolak-based photoresists may be used because an active component for silylation is novolak. For shorter wavelengths, e.g., 248 nm, the polymeric resin may be polyhydroxystyrene (PHS). Both novolak and PHS are phenolic polymers. More recently, resists for DUV applications have moved away from phenolic polymers, with the trend being toward the use of acrylates.

In another embodiment, layer 104 is formed of a surface imaging material that has silicon incorporated therein and therefore does not require a separate silylation operation. Examples of such surface imaging materials include bi-layer resist products such as the TIS 2000™ photoresist system, which is commercially available from Arch Chemicals, Inc., and the SiBER™ photoresist system, which is commercially available from Shipley Company, L.LC. The SiBER™ photoresist system includes a silicon-containing top imaging layer and a planarizing underlayer.

As described above, known CARL patterning processes are bi-layer processes in which a planarization layer is used to provide local and global planarization for a thin layer of surface imaging material formed thereon. In contrast, in the method of the present invention the surface imaging material may be formed directly on the layer of low k material. The reason that the surface imaging material may be formed directly on a spun-on layer of low k material is that spin coating yields a substantially planar surface. In the case of doped oxides, the reason that the surface imaging material may be formed directly on the doped oxide layer is that the deposition of a layer by CVD on a planarized surface also yields a substantially planar surface.

As shown in FIG. 2B, layer 104 of surface imaging material has been exposed and developed using known techniques to define a pattern therein. In addition, the patterned surface imaging material has been hardened by exposure to an oxygen containing plasma so that it will function as a hardmask during pattern transfer to the layer 102 of low k material, as will described in more detail below. It will be apparent to those skilled in the art that in applications where the surface imaging material does not contain silicon in the as-formed state, the surface imaging material needs to have silicon incorporated therein, e.g., by silylation, before being exposed to the oxygen containing plasma. The layer 104 of surface imaging material may be formed using any suitable technique, e.g., a spin-on technique, and, in one embodiment, has a thickness in the range from about 500 angstroms to about 2,500 angstroms. As used herein, the term “about” means that the specified dimension or parameter may be varied within an acceptable manufacturing tolerance for a given application. In one embodiment, the acceptable manufacturing tolerance is ±10%.

The patterned surface image material may be silylated using known techniques. In the case of CARL surface imaging materials, a wet silylation process using silylation solutions such as CS-248-Hex or AZ CSS SILYLATION SOLUTION, both of which are commercially available from Clariant AG, may be used. In the case of novolak-based, PHS-based, and acrylate-based photoresists, a dry silylation process may be used, e.g., the DESIRE process or the SABRE process. In the case of silicon-containing surface imaging materials, e.g., the materials in the TIS 2000™ and the SiBER™ photoresist systems, a separate silylation operation is not necessary because silicon is already incorporated in these materials as formed.

Next, the pattern defined in the surface imaging material is transferred to the low k material. FIG. 2C shows layer 104 of hardened surface imaging material and layer 102 of low k material after the pattern transfer has been completed. The pattern transfer may be accomplished using any suitable technique, e.g., plasma etching with an oxygen-containing chemistry having good selectivity to the hardened surface imaging material. During the pattern transfer process, layer 104 of hardened surface imaging material functions as a hardmask to prevent overetching of the low k material. Thereafter, in certain applications, layer 104 of hardened surface imaging material may act as a stop layer for a chemical mechanical planarization (CMP) process.

It will be apparent to those skilled in the art that the method for patterning a layer of a low k material of the present invention provides a number of significant technical advantages relative to the prior art. First, the method reduces the number of process steps required to pattern a low k material. This makes the process flow for an IC less complex and less expensive. Second, the method does not use standard photoresist coated on a hardmask in the patterning process. Thus, there is no need to remove residual photoresist from the hardmask once the low k material has been etched. Third, the method increases the etch rate of the low k material. The reason for this increased etch rate is that the elimination of the standard photoresist reduces loading. Fourth, because of such reduced loading, the method may enhance rate and profile control in the narrowest features.

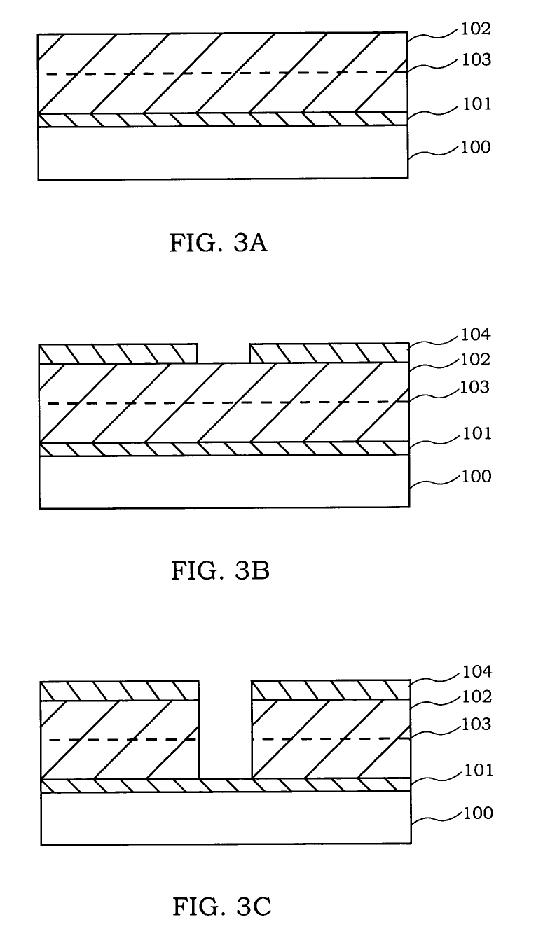

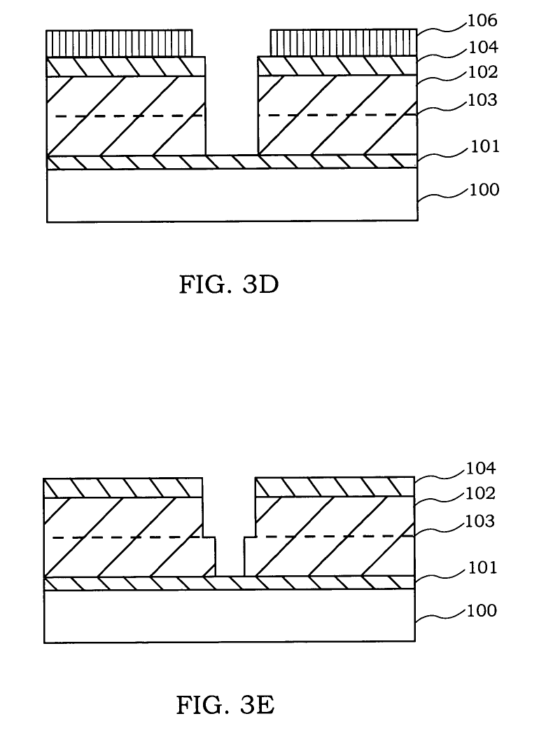

FIGS. 2A to 2C illustrate one embodiment of the method of the present invention in the context of a damascene application. The method of the present invention also may be used in dual damascene applications. FIGS. 3A to 3E illustrate another embodiment of the method of the present invention in a via first dual damascene application. FIG. 3A shows substrate 100 with diffusion barrier 101 and layer 102 of low k material formed thereon. Substrate 100 may be a metal layer, e.g., aluminum and copper. Diffusion barrier 101 may be formed of any suitable material, e.g., silicon nitride or silicon carbide, using known techniques. Depending on manufacturing issues, the thickness of diffusion barrier 101 may be in the range from about 300 angstroms to about 1,500 angstroms, with a thickness of about 500 angstroms being preferred. The thickness of layer 102 of low k material is preferably in the range between about 3,000 angstroms and about 10,000 angstroms. If desired, an optional intermediate layer 103, which is indicated by the dotted line, may be provided in roughly the middle of layer 102 of low k material. Intermediate layer 103 may be formed of the same material and have the same thickness as diffusion barrier 101.

Next, a layer of surface imaging material is applied on the layer of low k material and patterned to define a via in the low k material. FIG. 3B shows layer 104 of surface imaging material on layer 102 of low k material after it has been exposed, developed, and hardened in the manner described above. The pattern defined in the layer of surface imaging material is then transferred to the layer of low k material to form a via therein. FIG. 3C shows layer 102 of low k material after it has been etched to form the via.

As the method continues, standard photoresist is spun on the layer of hardened surface imaging material and patterned to define a trench in the low k material. FIG. 3D shows photoresist 106 on layer 104 of hardened surface imaging material after it has been patterned. Photoresist 106 may be spun on as a very thin layer and then exposed and developed in accordance with known techniques to define the trench pattern. The thickness of photoresist 106 needs to be thick enough to mask layer 104 of hardened surface imaging material, yet thin enough so that it is completely eroded during the trench etch process. If necessary, a bottom antireflective coating (BARC) (not shown) may be used in the patterning process. Next, the layer of low k material is etched to form the trench therein. FIG. 3E shows layer 102 of low k material after it has been etched to form the trench. As shown in FIG. 3E, the trench extends only partially, e.g., halfway, through layer 102 of low k material. If present, the trench etch may stop on intermediate layer 103. Alternatively, the trench etch may be a timed etch or use another endpoint to provide the desired depth. Once the trench is formed, the final step is to etch through diffusion barrier 101 at the bottom of the via. When intermediate layer 103 is present, this etch will usually remove the exposed area of the intermediate layer as well.

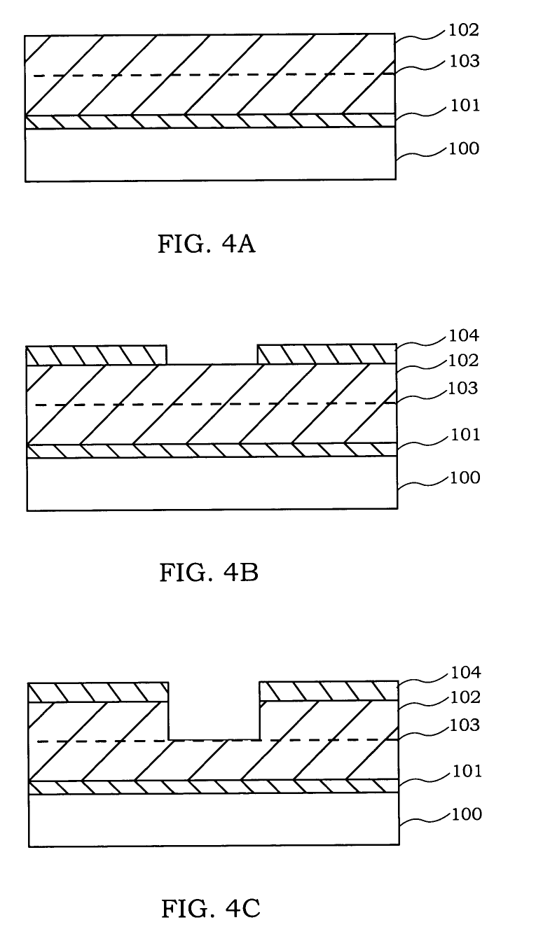

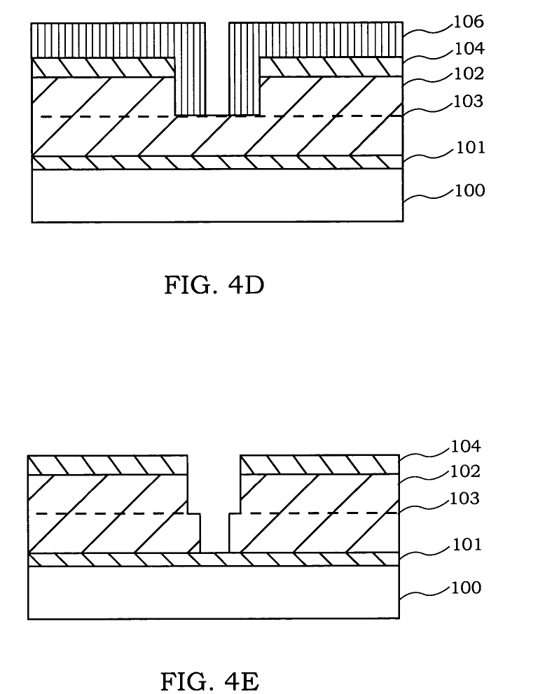

FIGS. 4A to 4E illustrate yet another embodiment of the method of the present invention in a trench first dual damascene application. FIG. 4A shows substrate 100 with diffusion barrier 101, layer 102 of low k material, and optional intermediate layer 103 (indicated by the dotted line) formed thereon. Next, a layer of surface imaging material is applied on the layer of low k material and patterned to define a trench in the low k material. FIG. 4B shows layer 104 of surface imaging material on layer 102 of low k material after it has been exposed, developed, and hardened in the manner described above. The pattern defined in the layer of surface imaging material is then transferred to the layer of low k material to form a trench therein. FIG. 4C shows layer 102 of low k material after it has been etched to form the trench. As shown in FIG. 4C, the trench extends only partially, e.g., halfway, through layer 102 of low k material. If present, the trench etch may stop on intermediate layer 103. Alternatively, the trench etch may be a timed etch or use another endpoint to provide the desired depth.

As the method continues, standard photoresist is spun on the layer of hardened surface imaging material and patterned to define a via in the low k material. FIG. 4D shows photoresist 106 on layer 104 of hardened surface imaging material after it has been patterned. Photoresist 106 may be spun on as a very thin layer and then exposed and developed in accordance with known techniques to define the via pattern. The thickness of photoresist 106 needs to be thick enough to form a planarized layer over the trench, yet thin enough so that it is completely eroded during the via etch process. If necessary, a bottom antireflective coating (BARC) (not shown) may be used in the patterning process. Next, the layer of low k material is etched to form the via therein. FIG. 4E shows layer 102 of low k material after it has been etched to form the via. If present, intermediate layer 103 needs to be etched open before the via is etched. Once the via is formed, the final step is to etch through diffusion barrier 101 at the bottom of the via. When intermediate layer 103 is present, this etch will usually remove the exposed area of the intermediate layer as well.

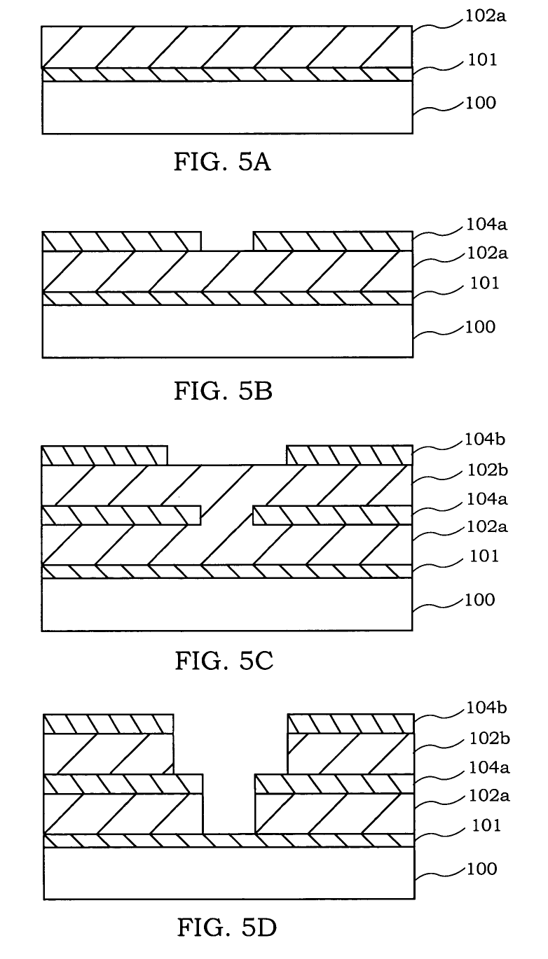

FIGS. 5A to 5D illustrate still another embodiment of the method of the present invention in a self-aligned dual damascene application. FIG. 5A shows substrate 100 with diffusion barrier 101 and a first layer 102a of low k material formed thereon. In this embodiment, the thickness of first layer 102a of low k material is preferably in the range from about 3,000 angstroms to about 5,000 angstroms, i.e., about half the thickness of the layer of low k material in the via first and trench first schemes described above. Next, a first layer of surface imaging material is applied on the first layer of low k material and patterned to define a via therein. FIG. 5B shows first layer 104a of surface imaging material on first layer 102a of low k material after it has been exposed, developed, and hardened in the manner described above.

As the method continues, a second layer of low k material and a second layer of surface imaging material are formed over the first layer of surface imaging material. The second layer of surface imaging material is patterned to define a trench in the second layer of low k material. FIG. 5C shows second layer 104b of surface imaging material formed on second layer 102b of low k material after it has been exposed, developed, and hardened in the manner described above. The thickness of second layer 102b of low k material is preferably approximately the same as that of first layer 102a of low k material. Thus, the total thickness of layers 102a and 102b of low k material is approximately the same as the thickness of layer 102 of low k material in the via first and trench first schemes described above. Next, the trench and via are etched into the first and second layers of low k material, respectively, in a one-step etch process. FIG. 5D shows second layer 102b of low k material with the trench etched therein and first layer 102a of low k material with the via etched therein. Once the trench and via are formed, the final step is to etch through diffusion barrier 101 at the bottom of the via.

In summary, the present invention provides a method for patterning a layer of a low k material in which a surface imaging material is applied directly on the layer of the low k material. The invention has been described herein in terms of several preferred embodiments. Other embodiments of the invention will be apparent to those skilled in the art from consideration of the specification and practice of the invention. The embodiments and preferred features described above should be considered exemplary, with the invention being defined by the appended claims and equivalents thereof.

What is claimed is:

1. A method for patterning a layer of a low dielectric constant material, comprising:
applying a surface imaging material on a layer of a low dielectric constant material, the surface imaging material having a thickness in the range from about 500 angstroms to about 2,500 angstroms;
defining a pattern in the surface imaging material;
hardening the patterned surface imaging material so that the patterned surface imaging material functions as a hard mask; and
transferring the pattern defined in the surface imaging material to the layer of the low dielectric constant material.

2. The method of claim 1, wherein the low dielectric constant material is selected from the group consisting of doped oxides, organic materials, and nanoporous materials.

3. The method of claim 1, wherein the low dielectric constant material is a low dielectric constant polymeric material having a dielectric constant below about 3.0.

4. The method of claim 1, wherein the hardening of the patterned surface imaging material includes incorporating silicon into the patterned surface imaging material and exposing the patterned surface imaging material to an oxygen containing plasma.

5. The method of claim 1, wherein the surface imaging material has silicon incorporated therein, and the hardening of the patterned surface imaging material includes exposing the patterned surface imaging material to an oxygen containing plasma.

6. A method for forming an integrated circuit, comprising:
forming a layer of a low dielectric constant material on a substrate;
applying a surface imaging material on the layer of the low dielectric constant material, the surface imaging material having a thickness in the range from about 500 angstroms to about 2,500 angstroms;
defining a pattern in the surface imaging material;
hardening the patterned surface imaging material so that the patterned surface imaging material functions as a hard mask; and
transferring the pattern defined in the surface imaging material to the layer of the low dielectric constant material.

7. The method of claim 6, wherein the layer of low dielectric constant material has a thickness in the range from about 3,000 angstroms to about 10,000 angstroms.

8. The method of claim 6, wherein the substrate is a layer of metal coated with a diffusion barrier.

9. The method of claim 8, wherein the pattern transferred to the layer of the low dielectric constant material defines a via therein, and the method further comprises:
forming a layer of photoresist material over the hardened surface imaging material;
defining a trench pattern in the layer of photoresist material; and
transferring the trench pattern into a portion of the layer of the low dielectric constant material.

10. The method of claim 8, wherein the pattern transferred to the layer of the low dielectric constant material defines a trench in an upper portion of the layer of the low dielectric constant material, and the method further comprises:
forming a layer of photoresist material over the hardened surface imaging material and the trench defined in the low dielectric constant material;
defining a via pattern in the layer of photoresist material; and
transferring the via pattern into a lower portion of the layer of the low dielectric constant material.

11. The method of claim 8, wherein the layer of the low dielectric constant material forms a first dielectric layer, the pattern transferred to the first dielectric layer defines a via therein, and the method further comprises:
forming a second dielectric layer over the surface imaging material applied on the first dielectric layer, the second dielectric layer being formed of a low dielectric constant material;
applying the surface imaging material on the second dielectric layer;
defining a trench pattern in the surface imaging material applied on the second dielectric layer;
hardening the patterned surface imaging material applied on the second dielectric layer so that the patterned surface imaging material applied on the second dielectric layer functions as a hardmask; and
transferring the trench pattern defined in the surface imaging material applied on the second dielectric layer to the second dielectric layer in the same process used to transfer the via pattern to the first dielectric layer.

12. The method of claim 6, wherein the low dielectric constant material is selected from the group consisting of doped oxides, organic materials, and nanoporous materials.

13. The method of claim 6, wherein the low dielectric constant material is a low dielectric constant polymeric material having a dielectric constant below about 3.0.

14. The method of claim 6, wherein the hardening of the patterned surface imaging material includes incorporating silicon into the patterned surface imaging material and exposing the patterned surface imaging material to an oxygen containing plasma.

15. The method of claim 6, wherein the surface imaging material has silicon incorporated therein, and the hardening of the patterned surface imaging material includes exposing the patterned surface imaging material to an oxygen containing plasma.

16. A method for patterning a layer of a low dielectric constant polymeric material, comprising:
applying a surface imaging material on a layer of a low dielectric constant polymeric material, the surface imaging material having a thickness in the range from about 500 angstroms to about 2,500 angstroms;
defining a pattern in the surface imaging material;
hardening the patterned surface imaging material so that the patterned surface imaging material functions as a hard mask; and
transferring the pattern defined in the surface imaging material to the layer of the low dielectric constant polymeric material.

17. The method of claim 16, wherein the low dielectric constant polymeric material has a dielectric constant below about 3.0.

18. The method of claim 16, wherein the hardening of the patterned surface imaging material includes incorporating silicon into the patterned surface imaging material and exposing the patterned surface imaging material to an oxygen containing plasma.

19. The method of claim 16, wherein the surface imaging material has silicon incorporated therein, and the hardening of the patterned surface imaging material includes exposing the patterned surface imaging material to an oxygen containing plasma.

20. A method for patterning a layer of a low dielectric constant material, comprising:
applying a surface imaging material on a layer of a low dielectric constant material;
defining a pattern in the surface imaging material;
hardening the patterned surface imaging material so that the patterned surface imaging material functions as a hard mask; and
transferring the pattern defined in the surface imaging material to the layer of the low dielectric constant material.

21. The method of claim 20, wherein the low dielectric constant material is selected from the group consisting of doped oxides, organic materials, and nanoporous materials.

22. The method of claim 20, wherein the low dielectric constant material is a low dielectric constant polymeric material having a dielectric constant below about 3.0.

23. The method of claim 20, wherein the hardening of the patterned surface imaging material includes incorporating silicon into the patterned surface imaging material and exposing the patterned surface imaging material to an oxygen containing plasma.

24. The method of claim 20, wherein the surface imaging material has silicon incorporated therein, and the hardening of the patterned surface imaging material includes exposing the patterned surface imaging material to an oxygen containing plasma.
